(19) United States
(12) Patent Application Publication
(10) Pub. No.: US 2023/0212740 A1
(43) Pub. Date: Jul. 6, 2023

(54) METHODS AND SYSTEMS FOR SEMICONDUCTOR SUBSTRATE PROCESSING

(71) Applicant: ASM IP Holding, B.V., Almere (NL)

(72) Inventors: Chiyu Zhu, Helsinki (FI); Sukanya Datta, Helsinki (FI); Jan Willem Maes, Wilrijk (BE)

(21) Appl. No.: 18/147,376

(22) Filed: Dec. 28, 2022

Related U.S. Application Data
(60) Provisional application No. 63/295,692, filed on Dec. 31, 2021.

(51) Int. Cl. C23C 16/08; C23C 16/455; C23C 16/02; H01L 21/02

(52) U.S. Cl. CPC C23C 16/08; C23C 16/45525; C23C 16/0227; H01L 21/02046

(57) ABSTRACT

The present disclosure relates to methods and apparatuses for depositing a conductive layer on another conductive layer of a substrate. The method comprises providing the substrate comprising the first conductive layer in a reaction chamber, providing a cleaning agent comprising a metal halide into the reaction chamber in a vapor phase to clean the substrate and providing a second material precursor into the reaction chamber in a vapor phase to deposit the second conductive layer on the first conductive layer. The disclosure further relates to a method of forming a semiconductor structure and to a semiconductor processing assembly.

### FIELD

The present disclosure relates to methods and processing assemblies for the manufacture of semiconductor devices. More particularly, the disclosure relates to methods and assemblies for depositing conductive materials on a substrate, for cleaning substrate surfaces and for forming semiconductor structures.

### BACKGROUND

Semiconductor device manufacturing includes depositing various materials on top of one or more underlaying materials to form structures. In many occasions, achieving a low resistivity through the vertically assembled structures is desired, and accordingly, conductive materials, such as metals, are used. The interface between two vertically adjacent material layers may be a major point of increased resistivity in the structure, and thus, in addition to surface roughness control of the first-deposited material, surface cleaning is commonly performed. Various radical-based etching methods have been developed in the art to clean the substrate surface prior to depositing additional conductive materials. Such surface cleaning may easily result in surface damage, and/or cause excessive etching of the surface being cleaned.

Accordingly, improved methods and systems for depositing conductive material layers, forming structures and cleaning substrate surfaces are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of depositing a second conductive layer on a first conductive layer of a substrate, to a method of cleaning a substrate surface, to a semiconductor structure and a device, and to semiconductor processing assemblies for depositing a conductive layer on a substrate.

In one aspect, a method of depositing a second conductive layer on a first conductive layer of a substrate is disclosed. The method comprises providing the substrate comprising the first conductive layer in a reaction chamber, providing a cleaning agent comprising a metal halide into the reaction chamber in a vapor phase to clean the substrate and providing a second material precursor into the reaction chamber in a vapor phase to deposit the second conductive layer on the first conductive layer. The first conductive layer according to the current disclosure is at least partially oxidized, and cleaning the substrate comprises removing material from the first conductive layer. In some embodiments, depositing a second metal on the first conductive layer of the substrate is a selective deposition process. In some embodiments, cleaning the substrate and depositing the second conductive material are performed in the same reaction chamber. In some embodiments, cleaning the substrate and depositing the second conductive material are performed in different reaction chambers. In some embodiments, cleaning the substrate and depositing the second conductive material are performed in different deposition stations of the same reaction chamber.

In some embodiments, the first conductive layer comprises an elemental metal or a semimetal, metal nitride or a metal carbide. By elemental metal is herein meant metal with an oxidation state of zero. In some embodiments, the first conductive layer comprises titanium nitride. In some embodiments, the first conductive layer comprises titanium carbide. In some embodiments, the first conductive layer comprises niobium carbide. In some embodiments, the first conductive layer comprises molybdenum carbide. In some embodiments, the first conductive layer comprises an elemental transition metal. In some embodiments, the first conductive layer comprises elemental ruthenium, molybdenum or a combination thereof. In some embodiments, the first conductive layer comprises elemental ruthenium. In some embodiments, the first conductive layer comprises elemental molybdenum. In some embodiments, the first conductive layer comprises elemental niobium. In some embodiments, the first conductive layer comprises silicon. In some embodiments, the first conductive layer comprises surface oxidation.

In some embodiments, the second conductive material comprises a metal. In some embodiments, the metal of the second conductive material is a transition metal. In some embodiments, the metal of the second conductive material is selected from metals of groups 5 and 6 of the periodic table of elements.

In some embodiments, the metal of the second conductive material is selected from a group consisting of titanium, zirconium, hafnium, vanadium, niobium, tantalum, molybdenum, tungsten, ruthenium, cobalt, nickel and copper. In some embodiments, the metal of the second conductive material is selected from a group consisting of vanadium, niobium, tantalum, molybdenum and tungsten. In some embodiments, the metal of the second conductive material is deposited as an elemental metal.

In some embodiments, the first conductive layer comprises a metal, the second conductive layer comprises a metal and the metal of the first conductive layer and the second conductive layer are the same. In some embodiments, the first conductive layer comprises a metal, the second conductive layer comprises a metal, and the cleaning agent comprises a metal halide of the metal in the first conductive layer or in the second conductive layer. In some embodiments, the second metal, the metal of the first conductive layer and the metal of the metal halide cleaning agent are the same.

In some embodiments, the metal halide of the cleaning agent is selected from metal fluorides and metal chlorides. In some embodiments, the metal fluoride is a transition metal fluoride. In some embodiments, the transition metal fluoride is a fluoride of a group 5 or group 6 metal. In some embodiments, the metal chloride is a transition metal chloride. In some embodiments, the transition metal chloride is a chloride of a group 5 or group 6 metal. In some embodiments, the metal halide of the cleaning agent is selected from a group consisting of NbCl₅, NbF₅, TaCl₅, TaF₅, Tal₅, TaBr₅, MoCl₅, MoCl₆ MoF₆, WCl₅, WCl₆ and WF₆. In some embodiments, the metal halide of the cleaning agent is MoCl₅. In some embodiments, the metal halide of the cleaning agent is NbCl₅. In some embodiments, the metal halide of the cleaning agent is TaCl₅. In some embodiments, the metal halide of the cleaning agent is WCl₅. In some embodiments, the metal halide of the cleaning agent is WCl₆.

In some embodiments, the cleaning agent is provided into the reaction chamber for at least 10 seconds. In some embodiments, the cleaning agent is provided into the reaction chamber from about 10 seconds to about 20 minutes, or from about 10 seconds to about 10 minutes, or from about 10 seconds to about 5 minutes, or from about 10 seconds to about 2 minutes, or from about 10 seconds to about 1 minute. In some embodiments, the cleaning agent is provided into the reaction chamber from about 1 minute to about 20 minutes, or from about 2 minutes to about 20 minutes, or from about 5 minutes to about 20 minutes, or from about 8 minutes to about 20 minutes, or from about 10 minutes to about 30 minutes.

In some embodiments, the cleaning agent removes the first conductive layer at a rate from about 0.1 nm min⁻¹ to about 20 nm min⁻¹.

In some embodiments, the second material precursor is selected from a group consisting of metalorganic precursors and inorganic precursors. In some embodiments, the second material precursor comprises a metal halide. In some embodiments, the second material precursor comprises the same metal halide as the cleaning agent. In some embodiments, the second material precursor comprises a metal oxyhalide. In some embodiments, the second material precursor comprises an oxyhalide selected from a group consisting of MoOCl₄, MoO₂Cl₂, WOCl₄ and WO₂Cl₂.

In some embodiments, depositing the second metal comprises a cyclic deposition process. In some embodiments, the cyclic deposition process comprises an ALD process. In some embodiments, the cyclic deposition process comprises a cyclic CVD process. In some embodiments, the deposition process is performed at a temperature from about 300° C. to about 550° C.

In some embodiments, the method further comprises providing a reducing agent into the reaction chamber in a vapor phase. In some embodiments, the reducing agent is selected from a group consisting of molecular hydrogen, hydrazine and derivatives of hydrazine. In some embodiments, the reducing agent is provided into the reaction chamber after providing a cleaning agent into the reaction chamber. In some embodiments, the reducing agent is provided into the reaction chamber before providing a cleaning agent into the reaction chamber.

In some embodiments, the method further comprises performing an activation treatment before providing the second material precursor into the reaction chamber. In some embodiments, the activation treatment comprises providing ammonia into the reaction chamber. In some embodiments, the activation treatment comprises performing an oxidation and re-reduction treatment.

In some embodiments, the substrate further comprises a second surface, and providing the cleaning agent into the reaction chamber removes material from the second surface.

In one aspect, a method of cleaning a surface of a semiconductor substrate is disclosed. The method comprises providing a substrate with a first conductive layer in a reaction chamber; and providing a cleaning agent comprising a metal halide into the reaction chamber in a vapor phase to remove a metal oxide material from the surface.

In some embodiments, the substrate comprises a second surface of different chemical composition, and providing the cleaning agent into the reaction chamber removes metal contamination from the second surface. In some embodiments, the first conductive layer is a contact surface of a via. In some embodiments, the first conductive layer forms a bottom of a gap. In some embodiments, the gap comprises a side wall, and the side wall comprises a second material.

In a further aspect, a method of forming a semiconductor structure is disclosed. The method comprises providing a substrate comprising a first conductive layer in a reaction chamber, providing a cleaning agent comprising a metal halide into the reaction chamber in a vapor phase to clean the substrate and providing a second material precursor into the reaction chamber in a vapor phase to deposit the second conductive layer on the first conductive layer. In the method, the first conductive layer is at least partially oxidized, and cleaning the substrate comprises removing material from the first conductive layer.

In yet another aspect, a semiconductor processing assembly for depositing a second metal on a first conductive layer of a substrate is disclosed. The assembly comprises one or more reaction chambers constructed and arranged to hold the substrate and a reactant injector system constructed and arranged to provide a cleaning agent comprising a metal halide and second material precursor into the reaction chamber in a vapor phase. The processing assembly further comprises a reactant vessel constructed and arranged to contain and volatilize the cleaning agent and a precursor vessel constructed and arranged to contain and volatilize the second material precursor. The assembly according to the current disclosure is constructed and arranged to provide the cleaning agent via the reactant injector system to the reaction chamber to remove material from the first conductive layer and to provide the second material precursor via the reactant injector system to the reaction chamber to deposit second conductive layer on the first conductive layer of the substrate.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIGS. 1A and 1B illustrate a block diagram of exemplary embodiments of a method according to the current disclosure.

FIGS. 2A-2C are schematic presentations of a structure comprising a material deposited according to the current disclosure.

FIG. 3 is a schematic presentation of a processing assembly according to the current disclosure.

### DETAILED DESCRIPTION

The description of exemplary embodiments of methods, structures, devices and processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

In one aspect, a method of depositing a second conductive layer on a first conductive layer of a substrate is disclosed. The method comprises providing the substrate comprising the first conductive layer in a reaction chamber, providing a cleaning agent comprising a metal halide into the reaction chamber in a vapor phase to clean the substrate; and providing a second material precursor into the reaction chamber in a vapor phase to deposit the second conductive layer on the first conductive layer.

### Substrate

As used herein, the term “substrate” may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. A substrate according to the current disclosure comprises two surfaces having different material properties.

### Conductive Layer

As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

A second conductive layer may be deposited according to methods disclosed herein to form a stack of two or more first conductive layers. Thus, the surface on which the second conductive layer is deposited is a surface of a first conductive layer. A first conductive layer according to the current disclosure may be a meta layer with very low resistivity, such as a resistivity below 100 μΩ cm. However, a first conductive layer in embodiments according to the current disclosure may have significantly higher resistivity, such as up to 2,000 μΩ cm. In some embodiments, the resistivity of the first conductive layer is less or equal to 2,000 μΩ cm. In some embodiments, the resistivity of the first conductive layer is less or equal to 1,000 μΩ cm. In some embodiments, the resistivity of the first conductive layer is less or equal to 500 μΩ cm. For example, a titanium carbide material may have a resistivity of about 1,000 to about 2,000 μΩ cm. Niobium carbide may have a resistivity of about 400 μΩ cm, and molybdenum carbide a resistivity of about 500 to about 800 μΩ cm. In some embodiments, the first conductive layer may comprise silicon.

In some embodiments, the first conductive layer comprises an elemental metal or a semimetal, metal nitride or a metal carbide. In some embodiments, a first conductive layer comprises metallic material, such as titanium nitride or titanium carbide. In some embodiments, the first conductive layer consists essentially of, or consists of an elemental metal or a semimetal, metal nitride or a metal carbide. In some embodiments, the first conductive layer comprises titanium nitride. In some embodiments, the first conductive layer consists essentially of, or consist of titanium nitride. In some embodiments, the first conductive layer comprises titanium carbide. In some embodiments, the first conductive layer consists essentially of, or consists of titanium carbide. In some embodiments, the first conductive layer comprises niobium carbide. In some embodiments, the first conductive layer consists essentially of, or consists of niobium carbide. In some embodiments, the first conductive layer comprises molybdenum carbide. In some embodiments, the first conductive layer consists essentially of, or consists of molybdenum carbide. In some embodiments, the first conductive layer comprises an elemental transition metal. In some embodiments, the first conductive layer consists essentially of, or consists of an elemental transition metal. In some embodiments, the first conductive layer comprises elemental ruthenium, molybdenum or a combination thereof. In some embodiments, the first conductive layer consists essentially of, or consists of elemental ruthenium, molybdenum or a combination thereof. In some embodiments, the first conductive layer comprises, consists essentially of, or consists of elemental ruthenium. In some embodiments, the first conductive layer comprises, consists essentially of, or consists of elemental molybdenum. In some embodiments, the first conductive layer comprises, consists essentially of, or consists of elemental niobium. In some embodiments, the first conductive layer comprises silicon.

### Surface Oxide

The first conductive layer according to the current disclosure is at least partially oxidized, and cleaning the substrate comprises removing material from the first conductive layer. A first conductive layer according to the current disclosure may thus comprise a surface oxide. The material removed from the first conductive layer may be oxidized material. Also non-oxidized material is removed from the first conductive layer to some extent. For example, elemental metals, such as Mo and Ru become oxidized upon exposure to ambient atmosphere. Also other material, such as nitrides, for example titanium nitride, may contain an oxidized layer where the material is exposed to the environment (e.g. top surface). Thus, in some embodiments, the first conductive layer may comprise surface oxidation. By a surface oxide is meant herein oxidized material—such as an elemental metal, silicon nitride or a metal nitride—on the surface of the layer material that has been formed unintentionally during the substrate processing. A surface oxide may be formed during exposure of the substrate to ambient atmosphere, or to water vapor, for example. A surface oxide in the current disclosure may be unwanted. In other words, it may deteriorate the performance of the device in which the layer comprising the surface oxide is used. Further, a silicon layer, that may form a first conductive layer, may have a native oxide on its outer surface.

In some embodiments, a second conductive layer according to the current disclosure is deposited on a first conductive layer. However, the second conductive layer may be deposited on material comprising a semimetal. In some embodiments, the material on which the second conductive layer is deposited comprises silicon. In some embodiments, such material may be silicon nitride.

The resistivity of the combined layers may be desired to remain as low as possible. If the topmost surface of the first conductive layer is oxidized, the resistivity of the device or structure may increase. Thus, it may be advantageous to clean the surface of the first conductive layer before depositing the next material layer on it. In the embodiments of the current disclosure, cleaning of the first conductive layer may remove at least some of the oxidized material from the surface of the first conductive layer. In some embodiments, the oxidized material is removed completely or substantially completely from the surface of the first conductive layer. The removal of the material from the first conductive layer may be etching. The rate of removal of the material of the first conductive layer should be moderate, to allow controlling the amount of material removed. Too fast material removal may deteriorate the layer structure and/or performance. In some embodiments, the cleaning agent removes the first conductive layer material at a rate from about 0.1 nm min⁻¹ to about 20 nm min⁻¹. The conditions for removing the first conductive layer material may be selected so that removing a suitable thickness of the material takes from about a few seconds to about few minutes. For example, the duration of removing first conductive layer material may be about 5 seconds, about 10 seconds, about 30 seconds, about 1 minute, about 3 minutes or about 5 minutes. In some embodiments, from about 1 nm to about 5 nm of first conductive material is removed in the process according to the current disclosure. For the purposes of the current disclosure, removing first conductive material may mean that the material removed comprises an oxide material on the surface of, or mixed into, the bulk of the first conductive layer material. In some embodiments, substantially only an oxide material is removed. In some embodiments, oxide material and bulk material of the first conductive layer are removed.

Further, it may be desired that a cleaning process uses chemistry that does not interfere with the further deposition steps. Thus, the introduction of additional elements, for example, may be undesired. Thus, in some embodiments, the first conductive layer comprises a metal, and the second metal and the metal of the first conductive layer are the same. In some embodiments, the first conductive layer comprises a metal, and the metal halide of the cleaning agent comprises the second metal or the metal of the first conductive layer. In some embodiments, the second metal, the metal of the first conductive layer and the metal of the metal halide are the same.

### Reaction Chamber

The substrate comprising the first conductive layer according to the current disclosure is provided in a reaction chamber. The reaction chamber may form a part of a semiconductor processing assembly, such as a vapor processing assembly. The reaction chamber can form part of an atomic layer deposition (ALD) assembly. The reaction chamber can form part of a chemical vapor deposition (CVD) assembly. The assembly may be a single wafer reactor. Alternatively, the reactor may be a batch reactor. The assembly may comprise one or more multi-station deposition chambers. Various phases of method can be performed within a single reaction chamber or they can be performed in multiple reaction chambers, such as reaction chambers of a cluster tool. In some embodiments, the method according to the current disclosure is performed in a single reaction chamber of a cluster tool, but other, preceding or subsequent, manufacturing steps of the structure or device may be performed in additional reaction chambers of the same cluster tool. Optionally, an assembly including the reaction chamber can be provided with a heater to activate the reactions by elevating the temperature of one or more of the substrates and/or the reactants and/or precursors. The second conductive layer according to the current disclosure may be deposited in a cross-flow reaction chamber. The second conductive layer according to the current disclosure may be deposited in a cross-flow reaction chamber.

In some embodiments, cleaning the substrate and depositing the second conductive layer are performed in the same reaction chamber. In some embodiments, cleaning the substrate and depositing the second conductive layer are performed in different reaction chambers. In some embodiments, cleaning the substrate and depositing the second conductive layer are performed in different deposition stations of the same reaction chamber. Especially in embodiments, in which the cleaning agent comprises the same metal as the second conductive layer, it may be possible to perform the method in a single reaction chamber. This may offer advantages in increasing process throughput. Further, in processing assemblies comprising a multi-station chamber, it may be possible to perform cleaning and subsequent deposition in deposition stations of one chamber without risk of contaminating one processing station with chemistries used in the other.

### Cleaning the Substrate

In embodiments according to the current disclosure, the surface of the substrate, such as the first conductive layer is cleaned by a cleaning agent comprising a metal halogen. In some embodiments, the cleaning agent consists essentially of, or consists of the metal halogen.

When a substrate is cleaned by a cleaning agent by methods of the current disclosure, some material, especially oxidized material, of the first conductive layer is removed from the surface of the first conductive layer. However, the substrate may comprise material of the first conductive material as contamination on other surfaces. Such contamination may be removed at least partially by methods disclosed herein. Thus, in some embodiments, the substrate further comprises a second material surface, and providing the cleaning agent comprising a metal halide into the reaction chamber removes material from the second material surface. The second material surface may be, for example, a side wall of a gap, whereas the first conductive layer may form the bottom of the gap. In some embodiments, the second material surface comprises a dielectric material. The dielectric material may comprise, consist essentially of, or consist of, for example, silicon oxide. The dielectric material may comprise, consist essentially of, or consist of, for example, a high-k material, such a s hafnium oxide or zirconium oxide.

To clean the conductive material, the cleaning agent etches the surface of the conductive material. Therefore, the metal halogen in the cleaning agent functions as an etchant. Without limiting the current disclosure to any specific theory, the halogen of the metal halogen may function as an etchant. Specifically, the etching may happen in gas phase, as the cleaning agent is provided into the reaction chamber in a gas phase.

Cleaning is performed before deposition of a second conductive layer is performed. Thus, the second conductive layer is deposited on a cleaned surface. The duration of the cleaning may differ based on the specific cleaning agent used, as well as depending on the temperature and other process parameters used. Further, as described in more detail below, cleaning the substrate may comprise providing a reducing agent into the reaction chamber to reduce the conductive surface.

Cleaning of the conductive surface according to the current disclosure may be performed using a continuous flow of the cleaning agent. In some embodiments, the cleaning agent is provided into the reaction chamber in pulses. In some embodiments, the reaction chamber is purged between two consecutive pulses of the cleaning agent.

In some embodiments, the cleaning agent is provided into the reaction chamber for at least 10 seconds. In some embodiments, the cleaning agent is provided into the reaction chamber from about 10 seconds to about 20 minutes, or from about 10 seconds to about 10 minutes, or from about 10 seconds to about 5 minutes, or from about 10 seconds to about 2 minutes, or from about 10 seconds to about 1 minute. In some embodiments, the cleaning agent is provided into the reaction chamber from about 1 minute to about 20 minutes, or from about 2 minutes to about 20 minutes, or from about 5 minutes to about 20 minutes, or from about 8 minutes to about 20 minutes, or from about 10 minutes to about 30 minutes. In embodiments, in which the cleaning agent is provided into the reaction chamber in pulses, the times above mean the sum of pulsing times used. For example, from about 10 to about 300 pulses of cleaning agent may be provided into the reaction chamber. In some embodiments, the cleaning agent is provided into the reaction chamber in about 50, 100, 150 or about 200 pulses. The reaction chamber may be purged between cleaning agent pulses. Further, the reaction chamber may be purged before providing the cleaning agent into the reaction chamber and/or after providing the cleaning agent into the reaction chamber.

In some embodiments, the cleaning agent is provided into the reaction chamber in carrier gas. A carrier gas may be an inert gas. In some embodiments, the carrier gas comprises, consists essentially of, or consist of argon. In some embodiments, the flow speed of the carrier gas is from about 0.1 slm to about 1.5 slm.

### Purge

As used herein, the term “purge” may refer to a procedure in which vapor phase reactants, such as a cleaning agent, a precursor and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. Purging may be effected between two pulses of the same gas. For example, in cleaning the substrate, it may be advantageous to intermittently remove the products released from the substrate, for example, to avoid redeposition of the unwanted elements.

As another example, a purge, or purging may be provided between pulses of two precursors or between a precursor and a reactant. Purging may avoid or at least reduce gas-phase interactions between the two gases reacting with each other. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a layer is deposited does not move. For example in the case of spatial purges, a purge step can take the following form: moving a substrate from a first location to which a first precursor is supplied, through a purge gas curtain, to a second location to which a second precursor is continually supplied. Alternatively, purging may be effected by transferring a substrate from one processing station to another in a multi-station chamber. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

### Thermal Process

In some embodiments, the processes according to the current disclosure are thermal processes. In a thermal process, the chemical reactions are promoted by using a suitable temperature for the process in question. In some embodiments, an elevated temperature relevant to ambient temperature is used. Generally, temperature increase provides the energy needed for the reactions to take place, in the absence of other external energy sources, such as plasma, radicals, or other forms of radiation. Using a fully thermal process reduces the risk of damaging the already formed structures. A thermal gas-phase etching may, for example, allow a more isotropic etching of materials compared to processes utilizing a plasma.

The methods according to the current disclosure may be performed at a temperature from about 350° C. to about 550° C. In some embodiments, the temperature may be the susceptor temperature. In some embodiments, the susceptor temperature may be the set susceptor temperature. For example, a temperature during the method according to the current disclosure may be from about 350° C. to about 500° C., or from about 350° C. to about 450° C., or from about 350° C. to about 400° C. In some embodiments, a temperature during the method according to the current disclosure may be from about 370° C. to about 550° C., or from about 400° C. to about 550° C., from about 450° C. to about 550° C. or from about 400° C. to about 500° C. For example, a temperature during the method according to the current disclosure may be about 420° C., or about 460° C., or about 480° C., or about 490° C., or about or about 510° C.

In some embodiments, cleaning the substrate is performed in a substantially constant temperature. In some embodiments, cleaning the substrate and depositing a second conductive layer are performed in the same temperature. In some embodiments, cleaning the substrate and depositing a second conductive layer are performed in different temperatures. In some embodiments, a temperature of cleaning the substrate is higher than the temperature of depositing the second conductive layer. In some embodiments, a temperature of cleaning the substrate is lower than the temperature of depositing the second conductive layer.

In some embodiments, the deposition of a second conductive layer may comprise one or more plasma-enhanced phases. Further, during the manufacture of a semiconductor structure or device, various processes may be employed, some of which may utilize plasma.

### Cleaning Agent

In embodiments according to the current disclosure, a cleaning agent comprising a metal halogen is used to clean the surface of the substrate, such as the first conductive layer. In some embodiments, the cleaning agent consists essentially of, or consists of the metal halogen. The cleaning agent is provided into the reaction chamber in a vapor phase. Thus, the cleaning agent, such as a metal halogen, is a gaseous cleaning agent. The process according to the current disclosure comprises using a gas-phase cleaning agent.

In this disclosure, “gas” can include material that is a gas at normal temperature and pressure (NTP), a vaporized solid and/or a vaporized liquid, and can be constituted by a single gas or a mixture of gases, depending on the context. A cleaning agent and a second material precursor according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. However, in some embodiments, hydrogen (H₂) gas may be used as a reducing agent. A gas other than a process gas, i.e., a gas introduced without passing through a precursor injector system, other gas distribution device, or the like, can be used for, e.g., sealing the reaction space, and can include a seal gas.

Metal halogens suitable for the methods according to the current disclosure may include, for example chlorides and fluorides. In some embodiments, the metal halide is selected from metal fluorides and metal chlorides. In some embodiments, the metal fluoride is a transition metal fluoride. In some embodiments, the transition metal fluoride is a fluoride of a group 5 or group 6 metal. In some embodiments, the metal chloride is a transition metal chloride. In some embodiments, the transition metal chloride is a chloride of a group 5 or group 6 metal. In some embodiments, the metal halide is selected from a group consisting of NbCl₅, NbF₅, TaCl₅, TaF₅, TaI₅, TaBr₅, MoCl₅, MoCl₆, MoF₆, WCl₅, WCl₆ and WF₆. In some embodiments, the metal halide is MoCl₅. In some embodiments, the metal halide is NbCl₅. In some embodiments, the metal halide is TaCl₅. In some embodiments, the metal halide is WCl₅. In some embodiments, the metal halide is WCl₆.

Fluorine and chlorine may be halogens that may be able to etch material of the first conductive layer most readily. However, for some materials, under certain conditions, metal bromides, or even metal iodides may be suitable. For example, some sensitive materials may benefit from using less reactive halogens to avoid damage to the already formed structures. Further, if the oxidation of the first conductive layer is not very extensive, or otherwise less aggressive treatment is sufficient, bromine or iodine may present useful alternatives.

### Reducing Agent

In some embodiments, the method further comprises providing a reducing agent into the reaction chamber in a vapor phase. In some embodiments, the reducing agent is selected from a group consisting of molecular hydrogen, hydrazine and derivatives of hydrazine. In some embodiments, atomic hydrogen is used as a reducing agent. Atomic hydrogen may be generated through, for example, hot-wire-assisted dissociation. In some embodiments, hydrogen radicals may be used as a reducing agent. Hydrogen radicals may be generated through, for example, remote plasma. In some embodiments, the process according to the current disclosure is otherwise fully thermal, but hydrogen radicals are produced through plasma. In some embodiments, the reducing agent is provided into the reaction chamber after providing a cleaning agent comprising a metal halide into the reaction chamber. In some embodiments, the reducing agent is provided into the reaction chamber before providing a cleaning agent comprising a metal halide into the reaction chamber.

Combining the use of a cleaning agent comprising a metal halide and a reducing agent may have the advantage that the cleaning agent may remove metal or metal oxide contamination from all substrate surfaces, i.e. also from surfaces outside the first conductive material. A reducing agent, in contrast, may efficiently remove oxidation from the substrate surfaces, but it may not influence the presence of metal contamination on unwanted surfaces. In some embodiments, hydrogen may remove other impurities, such as organic contaminants, from the substrate.

Further, using a cleaning agent and a reducing agent may allow adjusting the respective reactivities of both treatments such that an optimal cleaning performance is achieved for a given surface or a combination of surfaces. Optimizing cleaning performance may include consolidating contradictory goals, for example, minimum process duration, maximum purification, minimum surface damage, maximum device performance, etc. Therefore, performing the cleaning process with two at least partially complementary approaches may offer advantages exceeding the cumulative benefits of each approach alone.

### Surface Activation

In some embodiments, the method according to the current disclosure comprises surface activation. A surface activation is performed after the first conductive layer has been cleaned. Thus, in some embodiments, the surface activation is performed after a cleaning agent has been provided into the reaction chamber. In some embodiments, the surface activation is performed after a cleaning agent has been provided into the reaction chamber and the reaction chamber has been subsequently purged. In some embodiments, the surface activation is performed after a reducing agent has been provided into the reaction chamber. In some embodiments, the surface activation is performed after a reducing agent has been provided into the reaction chamber and the reaction chamber has been subsequently purged.

Without limiting the current disclosure to any specific theory, a cleaning agent may leave residues on the substrate surface, i.e. on the first conductive layer and on any other surfaces exposed to the cleaning process, that inhibit following deposition processes. A treatment with a reducing agent may at least partially remove such residues, but not necessarily to a sufficient degree.

In some embodiments, the surface activation comprises providing ammonia (NH₃) in a vapor phase into the reaction chamber. Ammonia may react with a halogen remaining on the substrate surface releasing gaseous nitrogen and a hydrogen halogenide, such as HF or HCl, thus removing a halogen from the surface of the substrate.

In some embodiments, the surface activation comprises an oxidation and re-reduction treatment. The substrate—including the cleaned first conductive layer—is exposed to mild oxidation treatment which may lead to the removal of a surface-bound halogen. Thereafter, the surface is exposed to a reductive compound, such as hydrogen, to remove the newly formed oxide (i.e. to re-reduce the surface). Without limiting the current disclosure to any specific theory, the oxidation during the surface activation may be mild and carefully controlled, to avoid defeating the advantaged gained from the surface reduction by the cleaning agent used earlier in the process. The re-reduction treatment can be performed similarly as providing the reducing agent into the reaction chamber described above. The re-reduction treatment may be identical to providing the reducing agent into the reaction chamber described above.

### Depositing Second Conductive Layer

In the methods according to the current disclosure, a second conductive layer is deposited on the conductive layer. The second conductive layer is deposited on the substrate after the substrate has been cleaned with a cleaning agent, and an optional reducing agent. In some embodiments, the second conductive layer consists essentially of, or consists of elemental metal. In some embodiments, the material of the second conductive layer is selected from a group consisting of an elemental metal, a metal nitride and a metal carbide.

In embodiments, in which the second conductive layer comprises a metal, the metal may comprise elemental metal and other forms of the metal. For example, the metal deposited according to the current disclosure may have partly an oxidation state of 0, +2, +3, +4, +5 and/or +6.

In some embodiments, the second conductive layer comprises a metal. In some embodiments, the metal of the second conductive layer is a transition metal. In some embodiments, the metal of the second conductive layer is selected from metals of groups 5 and 6 of the periodic table of elements. In some embodiments, the metal of the second conductive layer is selected from a group consisting of titanium, zirconium, hafnium, vanadium, niobium, tantalum, molybdenum, tungsten, ruthenium, cobalt, nickel and copper. In some embodiments, the metal of the second conductive layer is selected from a group consisting of vanadium, niobium, tantalum, molybdenum and tungsten. In some embodiments, the metal of the second conductive layer is deposited as an elemental metal. In some embodiments, at least 60% of metal of the second conductive layer is deposited as elemental metal. In some embodiments, at least 80% or at least 90% of metal of the second conductive layer is deposited as elemental metal. In some embodiments, at least 93% or 95% of metal of the second conductive layer is deposited as elemental metal.

In some embodiments, the second conductive layer comprises, consists essentially of, or consists of elemental copper. In some embodiments, the second conductive layer comprises, consists essentially of, or consists of elemental molybdenum. In some embodiments, the second conductive material forms an underlayer of a contact.

In some embodiments, depositing the second conductive layer comprises a cyclic deposition process. In some embodiments, the cyclic deposition process comprises an ALD process. In some embodiments, the cyclic deposition process comprises a cyclic CVD process. In some embodiments, depositing the second conductive layer is performed at a temperature from about 350° C. to about 550° C., such as at about 460° C.

### Precursors

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may me an element or a compound that is not incorporated into the resulting compound or element to a significant extent. However, a reactant may also contribute to the resulting compound or element in certain embodiments.

As used herein, “a second material precursor” includes a gas or a material that can become gaseous and that can be represented by a chemical formula that includes an element, such as a metal, of the second conductive layer.

In some embodiments, a second material precursor is provided in a mixture of two or more compounds. In a mixture, the other compounds in addition to the second material precursor may be inert compounds or elements. In some embodiments, a second material precursor is provided in a composition. Compositions suitable for use as composition can include a second material compound and an effective amount of one or more stabilizing agents. Composition may be a solution or a gas in standard conditions. In vapor deposition processes according to the current disclosure, a second material precursor is volatilized to provide it into the reaction chamber in vapor phase.

In some embodiments, the second material precursor is selected from a group consisting of metalorganic precursors and inorganic precursors. In some embodiments, the second material precursor comprises a metal halide. In some embodiments, the second material precursor comprises the same metal halide used for cleaning the substrate. For example, the second material precursor may be selected from a group consisting of NbCl₅, NbF₅, TaCl₅, TaF₅, TaI₅, TaBr₅, MoCl₅, MoCl₆, MoF₆, WCl₅, WCl₆ and WF₆.

In some embodiments, the second material precursor comprises a metal oxyhalide. In some embodiments, the second material precursor comprises an oxyhalide selected from a group consisting of MoOCl₄, MoO₂Cl₂, WOCl₄ and WO₂Cl₂.

Using the same metal halide in depositing the second material layer as for cleaning the substrate may have the advantage that no additional reactants are introduced into the reaction chamber during substrate cleaning. The same metal halide may be used in etching and in deposition, as the conditions in the reaction chamber may differ during the different phases of the process. For example, a different temperature may be used, influencing the activity of the metal halide on the substrate surface. Further, without limiting the current disclosure to any specific theory, during cleaning, the concentration of the metal halide in the reaction chamber may be larger, and the residence time of the metal halide in the reaction chamber may be longer. This may affect the reactions to which the metal halide participates. For example, during deposition of second conductive material, the metal halide may be consumed in a reaction with a second precursor or a second material reactant before it significantly etches the substrate. Additionally, in cyclic deposition process, the second precursor or second material reactant may be selected to be reactive enough to increase the preference of the deposition over etching under the selected conditions.

In some embodiments, cleaning of the substrate and depositing the second conductive material may be performed in different reaction chambers. In some embodiments, cleaning of the substrate and depositing the second conductive material may be performed in the same reaction chamber. In some embodiments, cleaning of the substrate and depositing the second conductive material may be performed in different deposition stations of one reaction chamber. The selection between performing cleaning and deposition in the same or different deposition chambers may depend on the precursors used for the deposition, process temperature and other process parameters.

### Cyclic Deposition Process

In the current disclosure, the deposition of the second conductive layer may comprise a cyclic deposition process, such as an atomic layer deposition (ALD) process or a cyclic chemical vapor deposition (VCD) process. The term “cyclic deposition process” can refer to the sequential introduction of precursor(s) and/or reactant(s) into a reaction chamber to deposit material, such as second conductive layer, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors or between providing a precursor and a reactant in the reaction chamber.

The process may comprise one or more cyclic phases. For example, pulsing of a second material precursor and a second material reactant may be repeated to cyclically form a second material layer on the substrate. In some embodiments, the process comprises or one or more acyclic phases, such as cleaning the substrate before depositing the second material layer on the substrate. In some embodiments, the deposition process comprises the continuous flow of at least one precursor. In some embodiments, a reactant may be continuously provided in the reaction chamber. In such an embodiment, the process comprises a continuous flow of a reactant. In some embodiments, one or more of the precursors and/or reactants are provided in the reaction chamber continuously.

For example, a second material layer may be an elemental metal layer. In such embodiments, a second material reactant may be a second material reducing agent. In some embodiments, a second material layer may be a metal nitride layer. In such embodiments, a second material reactant may be a nitrogen precursor. In some embodiments, a second material layer may be a metal boride layer. In such embodiments, a second material reactant may be a boron precursor. In some embodiments, a second material layer may be a metal carbide layer. In such embodiments, a second material reactant may be a carbon precursor.

The term “atomic layer deposition” (ALD) can refer to a vapor deposition process in which deposition cycles, such as a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a second material precursor into the reaction chamber. In some embodiments, the cyclic deposition process comprises purging the reaction chamber after providing a second material reactant into the reaction chamber. In some embodiments, the cyclic deposition process comprises purging the reaction chamber after providing a second material precursor into the reaction chamber and after providing a second material reactant into the reaction chamber.

CVD-type processes typically involve gas phase reactions between two or more precursors and/or reactants. The precursor(s) and reactant(s) can be provided simultaneously to the reaction space or substrate, or in partially or completely separated pulses. The substrate and/or reaction chamber can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

In some embodiments, depositing a second conductive layer on the first conductive layer of the substrate is a selective deposition process. Thus, the second conductive layer, such as a metallic molybdenum layer or a molybdenum nitride layer or a molybdenum carbide layer may be selectively deposited substantially only, or only, on the first conductive layer.

### DRAWINGS

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

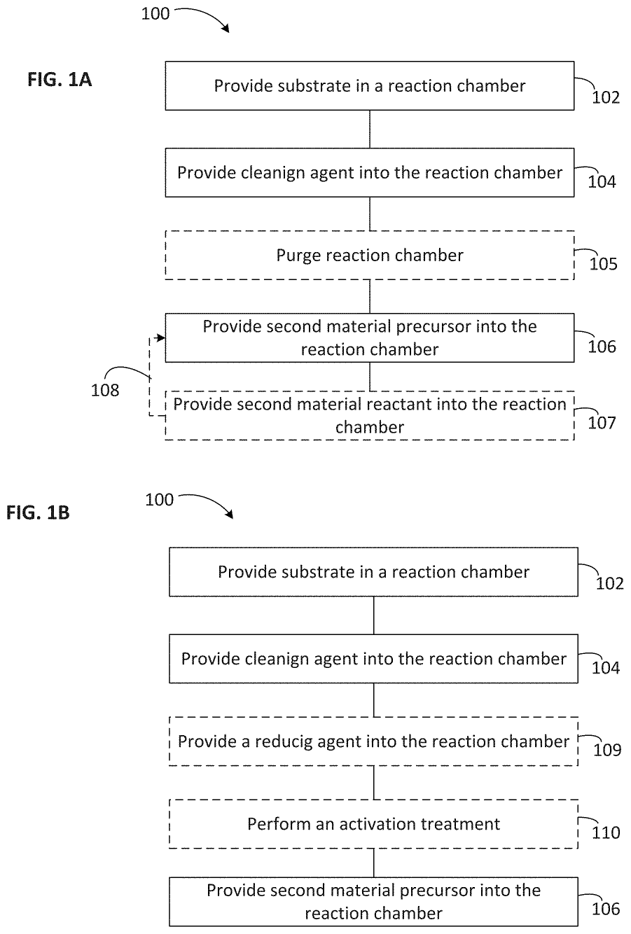

FIGS. 1A and 1B illustrate a block diagram of an exemplary embodiments of a method 100.

In the first phase 102, a substrate is provided into a reaction chamber. A substrate according to the current disclosure may comprise, for example, an oxide, such as silicon oxide (for example thermal silicon oxide or native silicon oxide), previously deposited layers and/or partially fabricated semiconductor devices, as described above. The first conductive material according to the current disclosure may be deposited on said surfaces.

The cleaning agent comprising a metal halide is provided in the reaction chamber containing the substrate at block 104. Without limiting the current disclosure to any specific theory, the cleaning agent may remove material from the substrate, especially from the first conductive layer. The removed material may be metal oxide material, such as a surface oxide on the first conductive layer. The duration of providing a cleaning agent into the reaction chamber 104 may be, for example, at least 10 seconds, such as 30 seconds, 1 minute or 15 minutes.

As a non-limiting experimental setup, the method 100 may be performed using elemental molybdenum as the first conductive material. A molybdenum layer may comprise a surface oxide. The thickness of the surface oxide may depend on the conditions to which the substrate has been exposed prior to performing the experiments. For example, the thickness of the surface oxide may be from about 0.5 nm to about 20 nm. In an exemplary test setup, the thickness of the surface oxide may be about 5 nm, about 10 nm or about 15 nm. The molybdenum layer (i.e. the first conductive layer) comprising the surface oxide may be exposed to molybdenum pentachloride (MoCl₅) as the cleaning agent. It was verified that, at a temperature of about 490° C., the thickness of the surface oxide may be reduced by about 7 nm by providing the cleaning agent (i.e. MoCl₅) into the reaction chamber for 50 seconds. The cleaning agent was provided into the reaction chamber in 50 pulses of 1 second. Similarly, providing the cleaning agent into the reaction chamber for 10 seconds in pulses of 1 second, the thickness of the surface oxide may be reduced by about 10 nm

As a comparative example, in a 400-second treatment (200 pulses of 2 seconds) by MoCl₅, more than about 8 nm of molybdenum oxide (thick oxidized layer on elemental molybdenum) was etched. In the same treatment, from about 2 to about 3 nm of an elemental molybdenum layer with a thin native oxide surface was etched.

In FIG. 1B, the first phases of the method 102 and 104 are performed similarly to the embodiment of FIG. 1A. However, in the embodiment of FIG. 1B, providing the cleaning agent into the reaction chamber at 104 is followed by providing a reducing agent into the reaction chamber at phase 109. The reducing agent may be, for example hydrogen gas. Providing a reducing agent into the reaction chamber is an optional step, and depending on the process specifics, may be omitted.

The following phase 110, namely performing an activation treatment, is also optional. It may be performed directly after providing a reducing agent into the reaction chamber 104. If the embodiment in question comprises providing a reducing agent into the reaction chamber, the activation treatment 110 may be performed after providing a reducing agent into the reaction chamber 109. Every phase described above may be followed by a purge, but they are omitted from the figure for brevity.

A second material precursor at phase 106 may thus be provided into the reaction chamber after providing a cleaning agent into the reaction chamber 104, after providing a reducing agent into the reaction chamber 109, after performing an activation treatment 110, or after a purge following any of the phases 104, 109 or 110.

In an exemplary embodiment, vapor-phase ammonia is provided into the reaction chamber for at least about 5 seconds, such as for about 10 seconds or for about 30 seconds or for about 60 seconds, or for about 75 seconds at a temperature of at least about 350° C. In some embodiments, ammonia is provided into the reaction chamber for less than about 120 seconds. The time needed for sufficient ammonia treatment depends on factors such as the ammonia flow speed and concentration, as well as the degree of surface blocking and substrate surface topology. In some embodiments, the temperature during providing ammonia into the reaction chamber is from about 420° C. to about 480° C., such as about 450° C. or about 465° C. or about 470° C.

In another exemplary embodiment, a mild oxidation treatment and a subsequent reduction were performed instead of an ammonia treatment to activate the substrate surface for the deposition of second conductive layer. Oxidation may be performed by exposure to an oxidant, such as ambient air, or other oxygen and/or water-containing gas. In some embodiments, gaseous water is used as an oxidant. In some embodiments, molecular oxygen is used as an oxidant. In some embodiments, oxygen and water are used as an oxidant. In some embodiments, oxidation may be performed at a temperature from about 400° C. to about 480° C., such as at a temperature of about 420° C., 450° C. or about 465° C. or about 470° C. The oxidation treatment may be performed for a suitable time to activate the substrate surface. As described above, an oxide layer on a first conductive layer is unwanted. Therefore, the level of oxidation is preferably to be kept at a minimum. A person skilled in the art may reasonably derive a suitable duration, temperature, gas-flow parameters and other process conditions for the oxidation treatment for each process. An exemplary duration of the oxidation process may be from about 10 to about 40 minutes.

To remove oxidized first conducting layer material, a reduction with gaseous hydrogen was performed. In some embodiments, the reduction may be performed at a same temperature as the preceding oxidation.

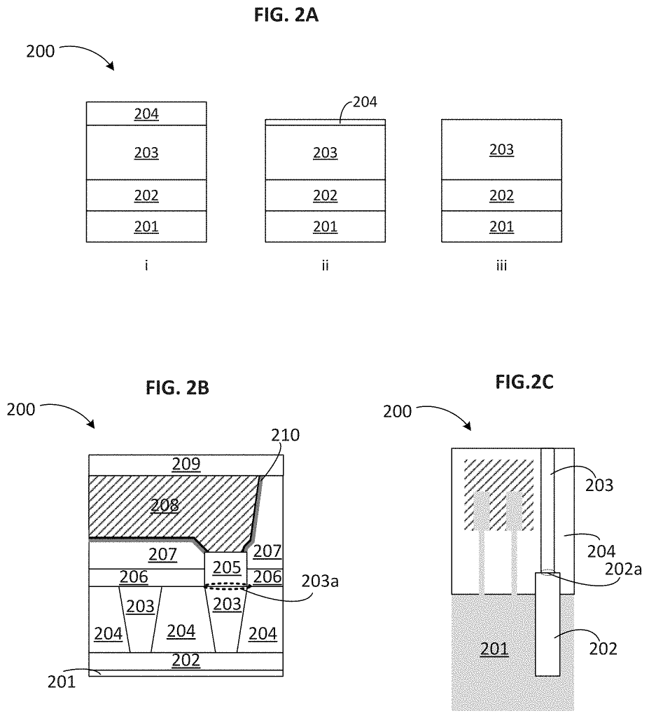

FIGS. 2A and 2B illustrate exemplary semiconductor structures according to the current disclosure.

In FIG. 2A, an exemplary embodiment of cleaning a first conductive material is described. First, at block i, a partially fabricated semiconductor device 200 comprising a substrate 201, comprising a thermal oxide layer 202 is overlaid with a first conductive layer 203. There is a surface oxide 204 on top of the first conductive layer 203. Block ii indicates the device after cleaning the device 200 with a cleaning agent. Cleaning the first conductive layer 203 decreases the thickness of the surface oxide 204. Although in the schematic FIG. 2A, there a continuous surface oxide 204 is visible in FIG. 2A, in some embodiments, the surface oxide 204 may be substantially completely removed. In some embodiments, there may be non-continuous areas of a surface oxide 204 remaining on the first conductive layer 203 after cleaning the device 200 with a cleaning agent according to the current disclosure.

Block iii indicates the device 200 after providing a reducing agent into the reaction chamber, causing the remaining surface oxide 204 to be reduced to a level similar to that of the metal, metallic or semimetal material of the bulk of the first conducting layer 203. As FIG. 2A is a schematic illustration of the process, the thickness of the different layers is not drawn to proportion. However, FIG. 2A indicates that cleaning a substrate may decrease the overall thickness of the first conductive layer 203 as a surface oxide 204 is removed. After cleaning the first conductive layer 203, a second conductive layer (not shown) may be deposited on the first conducive layer 203.

In FIG. 2B, a part of a semiconductor device comprising a first conductive layer 203 and a second conductive layer 205 is indicated. The device is formed on a silicon substrate 201 comprising a silicon nitride capping layer 202. In the embodiment of FIG. 2B, the first conductive layer 203 is a metal contact, such as a ruthenium or tungsten layer, that is embedded in a dielectric material 204 (such as silicon oxide) and connects the silicon nitride layer 202 with a via 205. The via 205 forms the second conductive layer, and it is surrounded by another silicon nitride capping layer 206 and a dielectric layer 207. In this position, the dielectric material may be, for example, silicon oxide or high k material. The via 205 (i.e. the second conductive layer) connects the metal contact 203 to a metal line 208. The metal line 208 may comprise a metal or metallic liner 210, and the whole structure may be covered by another silicon nitride capping layer 209.

The interface 203a, i.e. the surface that may be cleaned according to the methods described herein, is the top surface of the metal contact 203 before the deposition of the via 205. For maximal conductivity, the interface 203a should contain as little metal oxide as possible, in addition to otherwise well-conducting interface formed between the two material layers 203 and 205.

FIG. 2C illustrates another exemplary device 200 according to the current disclosure. In the Figure, a buried power rail (BPR) 202 is partially embedded into silicon 201. A metal connect 203 is formed on top of the BPR at specific locations along the length of the BPR 202. The metal connect 203 may be formed of, for example, molybdenum, ruthenium or of tungsten. The structure is surrounded by dielectric material 204, such as silicon dioxide. An exemplary device has been drawn to the left of the features described above, but as the details may vary, it is not discussed further in this context.

The interface 202a is an exemplary surface that may be cleaned according to the methods described herein. It is the top surface of the BPR 202 before the metal connect 203 is formed. It should be noted that a metal connect 203 is formed only in certain positions, and the connects 203 along a BPR 202 are separated from each other by the dielectric material 204. For maximal conductivity between the BPR 202 and the top of the metal connect 203, the interface 202a should contain as little metal oxide as possible, in addition to otherwise well-conducting connection formed between the two material layers 202 and 203.

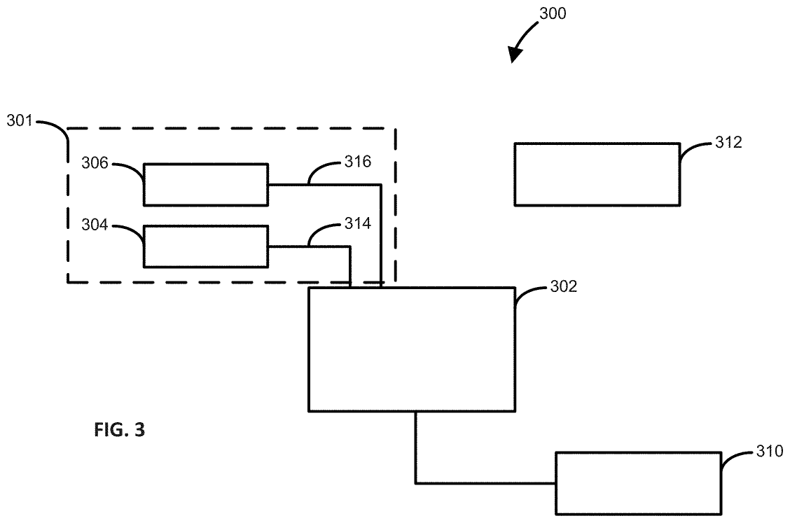

FIG. 3 illustrates a semiconductor processing assembly 300 according to the current disclosure in a schematic manner. The processing assembly 300 can be used to perform a method as described herein and/or to form a structure or a device, or a portion thereof as described herein.

In the illustrated example, processing assembly 300 includes one or more reaction chambers 302, a reactant injector system 301, a cleaning agent vessel 304, a second material precursor vessel 306, an exhaust source 310, and a controller 312. The processing assembly 300 may comprise one or more additional gas sources (not shown), such as an inert gas source, a carrier gas source and/or a purge gas source, as well as a second material reactant vessel. Further, a semiconductor processing assembly 300 may comprise a reducing agent vessel for providing a reducing agent into the reaction chamber 302.

Reaction chamber 302 can include any suitable reaction chamber, such as an ALD or CVD reaction chamber as described herein. The reaction chamber may be, for example, a single-wafer reaction chamber, or a multi-station deposition chamber comprising at least two deposition stations. Each of the deposition stations may be configured and arranged to perform a part of a process as described herein. In some embodiments, at least one of the deposition stations may be configured and arranged to perform a pre-treatment or a post-treatment before or after performing a current method, respectively.

The cleaning agent vessel 304 can include a vessel and a cleaning agent as described herein—alone or mixed with one or more carrier (e.g., inert) gases. A second material precursor vessel 306 can include a vessel and one or more second material precursors as described herein—alone or mixed with one or more carrier gases. A second material reactant source 308 can include a reactant or a precursor for providing another reactant or precursor for cyclic deposition of the second conductive material as described herein. Although illustrated with two source vessels 304, 306, a processing assembly 300 can include any suitable number of source vessels. Source vessels 304, 306 can be coupled to the reaction chamber 302 via lines 314, 316, which can each include flow controllers, valves, heaters, and the like. In some embodiments, cleaning agent in the cleaning agent vessel 304, the second material precursor in the second material precursor vessel 306 and/or the second material reactant in the second material reactant vessel may be heated. In some embodiments, a vessel is heated so that a precursor or a reactant reaches a temperature between about 70° C. and about 120° C., or between about 80° C. and about 100° C., such as about 85° C., about 90° C. or about 95° C.

Exhaust source 310 can include one or more vacuum pumps.

Controller 312 includes electronic circuitry and software to selectively operate valves, manifolds, heaters, pumps and other components included in the processing assembly 300. Such circuitry and components operate to introduce precursors, reactants and purge gases from the respective sources. Controller 312 can control timing of gas pulse sequences, temperature of the substrate and/or reaction chamber 302, pressure within the reaction chamber 302, and various other operations to provide proper operation of the processing assembly 300. Controller 312 can include control software to electrically or pneumatically control valves to control flow of precursors, reactants and purge gases into and out of the reaction chamber 302. Controller 312 can include modules such as a software or hardware component, which performs certain tasks. A module may be configured to reside on the addressable storage medium of the control system and be configured to execute one or more processes.

Other configurations of processing assembly 300 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 302. Further, as a schematic representation of a processing assembly, many components have been omitted for simplicity of illustration, and such components may include, for example, various valves, manifolds, purifiers, heaters, containers, vents, and/or bypasses.

During operation of the processing assembly 300, substrates, such as semiconductor wafers (not illustrated), are transferred from, e.g., a substrate handling system to reaction chamber 302. Once substrate(s) are transferred to reaction chamber 302, one or more gases from gas sources, such as precursors, reactants, carrier gases, and/or purge gases, are introduced into reaction chamber 302.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of depositing a second conductive layer on a first conductive layer of a substrate, the method comprising:
providing the substrate comprising the first conductive layer in a reaction chamber;
providing a cleaning agent comprising a metal halide into the reaction chamber in a vapor phase to clean the substrate; and
providing a second material precursor into the reaction chamber in a vapor phase to deposit the second conductive layer on the first conductive layer; wherein
the first conductive layer is at least partially oxidized, and wherein cleaning the substrate comprises removing material from the first conductive layer.

2. The method of claim 1, wherein the first conductive layer comprises an elemental metal or a semimetal, metal nitride or a metal carbide.

3. The method of claim 1, wherein the first conductive layer comprises an elemental transition metal.

4. The method of claim 1, wherein the first conductive layer comprises elemental ruthenium, molybdenum or a combination thereof.

5. The method of claim 1, wherein the second conductive layer comprises a metal.

6. The method of claim 5, wherein the metal is selected from metals of groups 5 and 6 of the periodic table of elements.

7. The method of claim 5, wherein the metal is selected from a group consisting of titanium, zirconium, hafnium, vanadium, niobium, tantalum, molybdenum, tungsten, ruthenium, cobalt, nickel and copper.

8. The method of claim 5, wherein the metal is deposited as an elemental metal.

9. The method of claim 1, wherein the first conductive layer comprises a metal, the second conductive layer comprises a metal and the metal of the first conductive layer and the second conductive layer are the same.

10. The method of claim 1, wherein the first conductive layer and the second conductive layer comprise a metal, and the cleaning agent comprises the metal halide of the metal in the first conductive layer or in the second conductive layer.

11. The method of claim 1, wherein the metal halide of the cleaning agent is selected from a group consisting of NbCl₅, NbF₅, TaCl₅, TaF₅, Tal₅, TaBr₅, MoCl₅, MoCl₆, MoF₆, WCl₅, WCl₆ and WF₆.

12. The method of claim 1, wherein the second material precursor is selected from a group consisting of metalorganic precursors and inorganic precursors.

13. The method of claim 1, wherein the second material precursor comprises a metal halide.

14. The method of claim 13, wherein the second material precursor comprises the same metal halide as the cleaning agent.

15. The method of claim 1, wherein depositing the second metal comprises a cyclic deposition process.

16. The method of claim 15, wherein the cyclic deposition process comprises an ALD process.

17. The method of claim 1, wherein the method further comprises providing a reducing agent into the reaction chamber in a vapor phase.

18. The method of claim 17, wherein the reducing agent is provided into the reaction chamber after providing the cleaning agent into the reaction chamber.

19. The method of claim 1, wherein the method further comprises performing an activation treatment before providing the second material precursor into the reaction chamber.

20. The method of claim 19, wherein the activation treatment comprises providing ammonia into the reaction chamber.

21. The method of claim 19, wherein the activation treatment comprises performing an oxidation and re-reduction treatment.

22. The method of claim 1, wherein the substrate further comprises a second material surface, and providing the cleaning agent into the reaction chamber removes material from the second material surface.

23. A method of cleaning a surface of a semiconductor substrate, the method comprising
providing a substrate with a first conductive layer in a reaction chamber;
providing a cleaning agent comprising a metal halide into the reaction chamber in a vapor phase to remove a metal oxide material from the surface.

24. The method of claim 23, wherein the substrate comprises a second surface of different chemical composition, and providing the cleaning agent into the reaction chamber removes metal contamination from the second surface.

25. The method of claim 23, wherein the first conductive layer is a contact surface of a via.
